(19) United States
(12) Patent Application Publication
(10) Pub. No.: US 2017/0186585 A1
(43) Pub. Date: Jun. 29, 2017

(54) ELECTRODE STRUCTURE FOR ICP ETCHER

(71) Applicant: Advanced Micro-Fabrication Equipment Inc, Shanghai, Shanghai (CN)

(72) Inventors: Rason Zuo, Shanghai (CN); Dee Wu, Shanghai (CN); Tuqiang Ni, Shanghai (CN)

(21) Appl. No.: 15/387,644

(22) Filed: Dec. 21, 2016

(30) Foreign Application Priority Data
Dec. 25, 2015 (CN) 201510995350.0

(51) Int. Cl. H01J 37/32

(52) U.S. Cl. CPC H01J 37/3211; H01J 37/32577; H01J 2237/334

(57) ABSTRACT

The invention relates to an electrode structure for ICP etcher, including: inductive coils, inductive coil connectors, connect rods and sleeve; in which, inductive coils are set on insulation window and insulation window is set on chamber lid; two ends of the connect rods respectively connect inductive coils and inductive coil connectors; the sleeve is made of conductive material and grounded; first end of the sleeve is covered by a cap while the second is opening; the cap has holes, and the connect rods are set pass through the holes and isolated from the cap; the opening of sleeve is set toward inductive coils, and the inductive coils are shielded inside the sleeve. This invention shields electromagnetic field generated by inductive coil connectors outside the sleeve to avoid influence of even electromagnetic field generated to inductive coils, and guarantee even etching.

### RELATED APPLICATION

This application claims priority benefit from Chinese Patent Application No. 201510995350.0, filed on Dec. 25, 2015, the entire content of which is incorporated herein by reference.

### FIELD OF INVENTION

This invention relates to the semiconductor etching technology field, particularly to an electrode structure for ICP etcher.

### BACKGROUND OF INVENTION

ICP (Inductively Coupled Plasma) etching is featured by high etching rate, high selection ratio and good uniformity in large area wafer processing art, and can be used in high quality and small size trench etching, and acquire favorable etching performance. It is widely used etching technology at present.

The processing mechanism of ICP etching is to form high density plasma, and the high density plasma induced high density reactive radicals, finally, both chemical reaction caused by reactive radical and physical effect caused by plasma bombardment can take effect to etching performance. The ICP etcher generates electromagnetic field by radio-frequency coil structure, and stimulates plasma by the electromagnetic field.

The attached figures FIG. 1 to FIG. 3 shows that FIG. 1 is the 3D schematic illustrating of ICP etcher electrode on chamber lid in prior art; FIG. 2 is the 3D structural illustrating of the electrode in FIG. 1; FIG. 3 is the top view of FIG. 1; electrode 13 is used to generate electromagnetic field stimulating plasma, including inductive coils 131, inductive coil connectors 132, 134 and connect rods 133 and 135; inductive coil connectors 132 connects inductance coils 131 through connect rods 133, and inductive coil connectors 134 connects inductive coils 131 through connect rods 135; inductive coils 131 is set on insulation window 12, and insulation window 12 is set on chamber lid 10; in use, chamber lid 10 is set on chamber body; inductive coil connectors 132 connects radio-frequency power supply, and 134 connects to grounding end; after power is on, the inductive coils 131 generates radio frequency electromagnetic field which is used to stimulate plasma. However, for such structure, the laterally arranged inductive coil connectors set above the inductive coils may affect the electromagnetic field generated by the inductive coils, causing uniform radio frequency electromagnetic field and uniform etching, and finally affect yield of products.

### DETAILED DESCRIPTION OF INVENTION

The present invention aims to provide an electrode structure used for ICP etcher and an ICP etcher, which eliminates impact of inductive coil connectors on electromagnetic field generated by inductive coils and improve the evenness of electromagnetic field.

In order to realize the above mentioned purpose, this invention provides the following technical plan:

An electrode structure for ICP etcher, including: inductive coils, inductive coil connectors, connect rods and sleeve; in which,

Inductive coils are set on insulation window and insulation window is set on chamber lid;

Two ends of the connect rods respectively connect inductive coils and inductive coil connectors;

The sleeve is made of conductive material and grounded; first end of the sleeve is covered by a cap while the second end is opening; the cap has holes, and the connect rods are set in the holes and isolated from the cap; the opening of sleeve is set toward inductive coils, and the inductive coils are shielded inside the sleeve.

Optional, the diameter of said holes on cap is larger than that of the connect rods so the holes and connect rods have gap so as to realize isolation between connect rods and cap.

Optional, an insulation pad is set between the holes and connect rods to make connect rods isolate from cap each other.

Optional, the opening of sleeve sets a flanging, by which the sleeve is fixed on chamber lid; the flanging contacts with chamber lid so as to make sleeve grounded through the chamber lid.

Optional, the structure contains snap ring and the second end of sleeve sets flanging, the sleeve is fixed onto insulation window by the flanging; the snap ring sets on outer wall of sleeve and contacts with chamber lid to make sleeve grounded through the chamber lid and snap ring.

Optional, the conductive material of sleeve is metal Cu, Al or Ag, or their combination, or magnetic shielding metal materials.

Optional, the inductive coils are circular, and the sleeve is cylindrical.

Optional, the part of connect rods covered by the sleeve is arranged vertically.

Optional, multiple connect rods connecting to inductive coils; the first connect rods connect to radio-frequency power supply through the first inductive coil connectors, and the second connect rods connect to grounding end through the second inductive coil connectors.

The electrode structure further includes multiple inductive coil connectors, the inductive coil connectors arranged laterally and above the cap of the sleeve. The electrode structure for ICP etcher and ICP etcher provided in this invention sets sleeve made of metal materials. One end of the sleeve sets cap, and makes connect rods inside through the holes on cap; the opening on other end of the sleeve is toward inductive coils and the inductive coils are shielded inside the sleeve. In that way, the inductive coil connectors are set outside the sleeve, while the sleeve is made of grounded metal material so as to shield electromagnetic field generated by inductive coil connectors outside the sleeve to avoid influence of even electromagnetic field generated by inductive coils, and guarantee even etching.

### BRIEF DESCRIPTION OF ATTACHED DRAWING

In order to clearly explain technical plan in the invention embodiment or existing technology, the attached drawings used in embodiment or technical description are introduced simply below. Apparently, the attached drawings described below are some embodiments of the invention. For common technicians in this field, they can acquire other drawings according to these drawings without paying creative labor.

FIG. 1 is the stereoscopic structure illustrating for electrode of ICP etcher set on chamber lid in prior art;

FIG. 2 is the stereoscopic structure illustrating for electrode in FIG. 1;

FIG. 3 is the top structure view of FIG. 1;

FIG. 4 is the stereoscopic structure illustrating for electrode of ICP etcher of the present invention;

FIG. 5 is the transparent stereoscopic structure illustrating of FIG. 1;

FIG. 6 is the top structure view of FIG. 4;

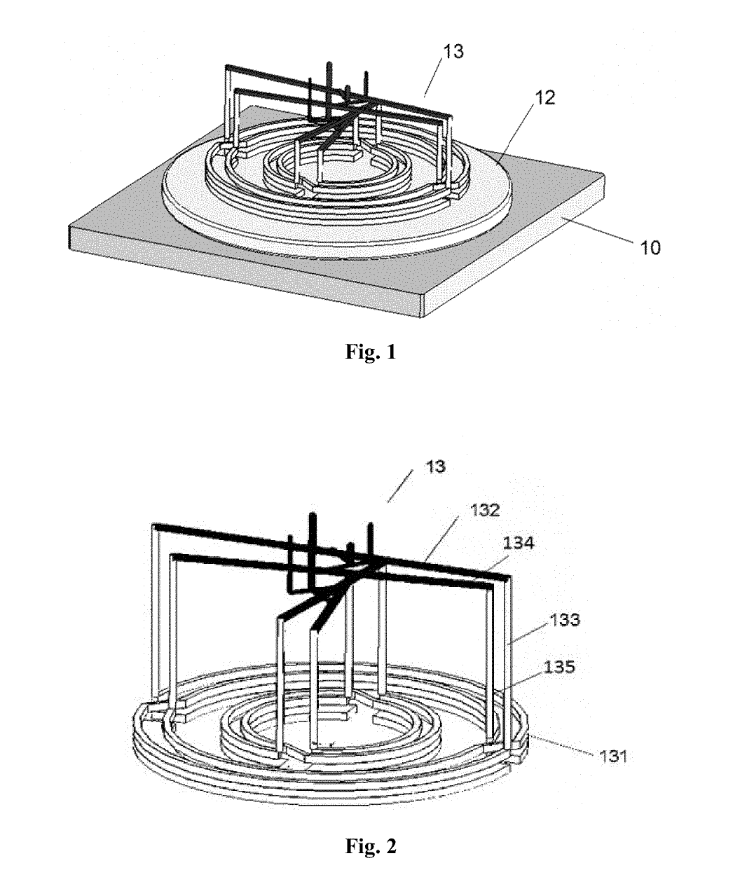

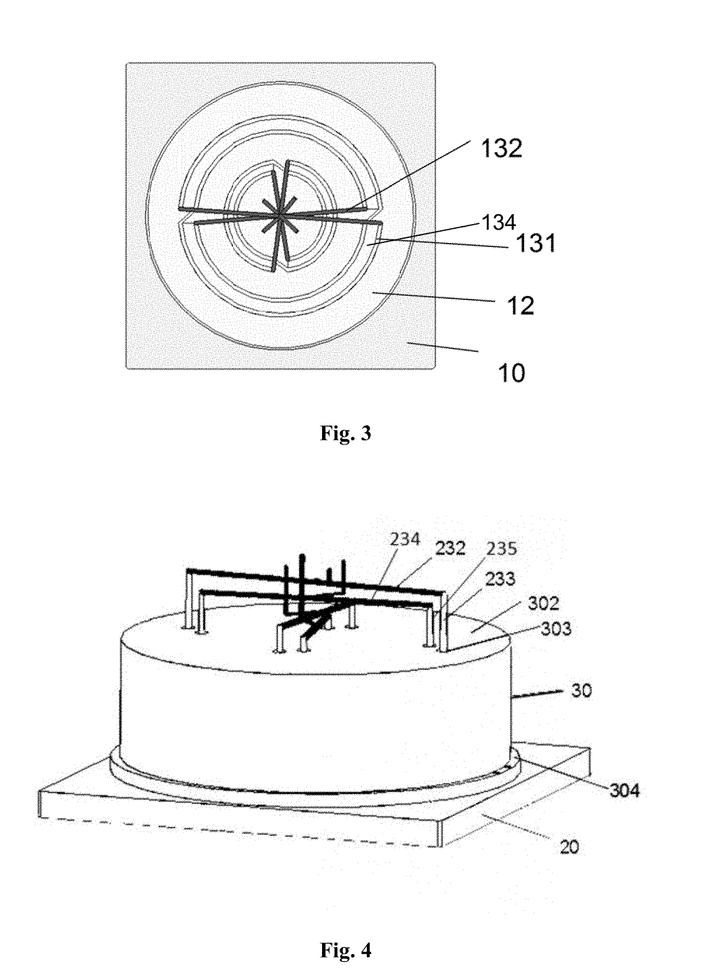

### DETAILED EXEMPLARY EMBODIMENT

Hereinafter, the preferred embodiments of the present invention will be further illustrated.

As described in background technology, in prior art, the electrode of ICP etcher is comprised of inductive coils, inductive coil connectors and connect rods connecting them, in which, the inductive coil connectors connect to radio-frequency power supply; after power is applied to the inductive coil, the inductive coils generate radio-frequency electromagnetic field to stimulate plasma. However, for such electrode structure set above the inductive coils, the inductive coil connectors connecting to power source may affect the electromagnetic field generated by the inductive coils, causing uneven radio frequency electromagnetic field and uneven plasma, finally affect evenness of etching and yield of products.

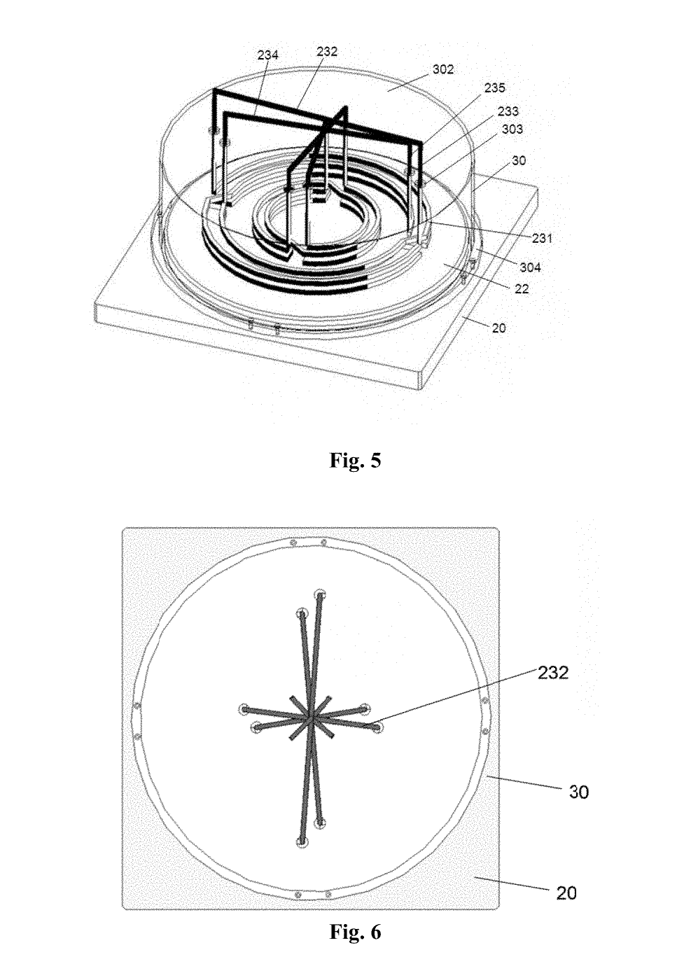

Based on aforesaid problems, this invention provides an electrode structure used for ICP etcher. According to FIG. 4-FIG. 5, FIG. 4 is the stereoscopic structure of electrode structure of this invention, and FIG. 5 is the stereoscopic structure illustrating of sleeve in FIG. 4 after transparent processing; FIG. 6 is the top view of structure of FIG. 4. The electrode structure includes: inductive coils 231, inductive coil connectors 232, connect rods 233 and sleeve 30; in which,

Inductive coils 231 is set on insulation window 22 and insulation window 22 is set on chamber lid 20;

Two ends of the connect rods 233 respectively connect inductive coils 231 and inductive coil connectors 232;

The sleeve 30 is made of conductive material and grounded; one end of the sleeve 30 is cap 302 while the other is opening; the cap 302 has multiple holes 303, and the multiple connect rods 233 is set in the holes 303 and isolated from the cap 302; the opening of sleeve 30 is set face toward inductive coils, and the inductive coils 231 are shielded inside the sleeve 30.

In the present invention, the sleeve made of metal. One end of the sleeve sets cap, and makes connect rods pass through the holes on cap; the opening on other end of the sleeve faces toward inductive coils and the inductive coils are shielded inside the sleeve. In that way, the inductive coil connectors are set outside the sleeve, while the sleeve is made of metal material and is grounded electromagnetic field generated by inductive coil connectors outside the sleeve is shielded to avoid influence of even electromagnetic field generated by inductive coils, and even etching guaranteed.

In the embodiment of this invention, FIG. 5 and FIG. 6 can be referred to. The electrode is comprised of inductive coils 231, inductive coil connectors 232 and connect rods 233, in which, the inductive coil connectors 232 connect with power supply; the power source is connected with inductive coils 231 by connect rods 233; the inductive coils receive radio frequency power so as to generate electromagnetic field to stimulate plasma. In this embodiment, not only connect rods 233 but also connect rods 235 connect with inductive coils 231; the connect rods 233 connects with radio frequency power source through inductive connectors 232 while connect rods 235 connects to grounding end by the second inductive connectors 234.

In accordance with different design requirements, the inductive coils 231 could be a planer inductive coils or a stereoscopic inductive coils, and could be spiral, asymptotic line shape, concentric cycle or circular. In one embodiment, the inductive coils 231 are a stereoscopic coil, including central coil and peripheral coil, both are comprised of upper and lower coil segment. The central coil is comprised of a group of circular coil segments, including two staggered non-closed loops; the peripheral coil is also comprised of a group of circular coil segments including two staggered non-closed loops; Every coil connects with inductive coil connectors 232 by connect rods 233. As required, multiple groups of periphery coil can be set, i.e. additional coil groups set outside the periphery coil. The central coil and periphery coil can connect with the same power source or with different power sources respectively to generate electromagnetic field required.

The electrode is fixed above insulation window 22 and insulation window 22 is fixed on chamber lid 20; insulation window 22 realizes insulation and isolation with chamber lid 20, and makes electrode and chamber lid 20 combined; when the chamber lid 20 is mounted on top opening of the chamber (not shown in the drawing), the electrode faces toward chamber; then, the electromagnetic field generated by inductive coils stimulates plasma for processing such as etching or sedimentation on substrate inside the chamber.

In this embodiment, a sleeve 30 is supplied. The sleeve 30 is made of conductive material and be grounded; one end of the sleeve 30 is cap 302 while the other is opening; the cap 302 has holes 303, and the connect rods 233 is set in the holes 303 and isolated from the cap 302; the opening of sleeve 30 faces toward inductive coils, and the inductive coils 231 are shielded inside the sleeve 30.

In this invention embodiment, the connect rods include first part positioned inside the sleeve 30 and second part positioned outside the sleeve. The first part of connect rods 233 is arranged vertically to inductive coils 231 so that the magnetic field in sleeve can be evenly distributed while the second part is shielded by the sleeve and free from interference to magnetic field generated by inductive coils inside the sleeve. The second part outside the sleeve could be arranged in any way.

It is necessary to note that the inductive coils 231 is enclosed inside the sleeve 30, which means inductive coils 231 are set inside the internal space of sleeve, but not contact with it, in other words, no electrical connection between them; being enclosed means the opening of sleeve is of close attached with the lower component insulation window so as to provide a sleeve with function of shielding. The inductive coil connectors are set outside the sleeve, while the sleeve is made of metal material and is grounded, the electromagnetic field generated by inductive coil connectors outside the sleeve can be shielded to avoid influence to even distributed electromagnetic field generated by inductive coils, and guarantee uniformly etching.

In the embodiment, the metal material of sleeve 30 is Cu, Al or Ag, or their combination, or magnetic shielding metal materials such as nick alloy.

Furthermore, in order to guarantee normal operation of inductive coils 231, the connect rods 233 is isolated from the cap 302 of sleeve 30; in other words, they have no electrical connection; in some embodiments, the holes 303 of cap 302 can be set with larger diameter to make the aperture of holes 303 of cap 302 is larger than the diameter of connect rods 233; in that way, after the connect rods 233 is set inside the holes 303, the outer wall of connect rods 233 can keep certain gap with side wall of holes 303 so that the connect rods 233 will not connect with cap 302 of the sleeve 30 and realize isolation.

In other embodiments, the insulation pad (not shown in the drawing) can be set between holes 303 and connect rods 233 to realize isolation between the connect rods 233 and cap 302. The insulation pad can be either set on outer wall of connect rods 233 or on inner wall of holes 303. In one case, insulation pad is a tube, and set on outer wall of the connect rods 233; in another case, insulation pad is a tube with boss, and clipped to inner wall of holes 303. The insulation pad structure here described is only for reference, and any structure could insulate the holes and connect rods are the embodiment of present invention.

In this invention, the sleeve 30 should be grounded, and the inductive coils 231 is enclosed inside the sleeve 30 so as to form Faraday shielding sleeve; for ICP etcher, the chamber lid 20 is grounded; in order to simplify structure, this invention realizes grounding and fixation of sleeve 30 by chamber lid 20. In the embodiment inductive coils are circular, more preferentially, sleeve 30 could be cylinder shaped so as to provide better magnetic field distribution in a closed space.

Specifically in some embodiments, as shown in FIG. 4, the opening of aforesaid sleeve 30 sets flanging 304, by which 304 the sleeve 30 is fixed to chamber lid 20; furthermore the flanging 304 contacts with chamber lid 20 so as to make sleeve 30 grounded through the chamber lid 30. In this embodiment, flanging 304 could be a ring structure around the opening of sleeve, or one or multiple sheet structure; bolts can be set on flanging 304 to fix it to the chamber lid 20. Since flanging 304 directly contacts with and is fixed to chamber lid 20, the opening of sleeve 30 is closed while the chamber lid 20 is grounded. In this way, while the sleeve 30 is fixed, the grounding of sleeve 30 can be realized.

In other embodiments, as shown in FIG. 4, in order to provide more compact structure, the sleeve could be fixed on insulation window 22, and snap ring contacting both sleeve and chamber lid 20 could be set to realize the sleeve be grounded. Specifically, a flanging is set onto the opening of sleeve 30, by which the sleeve 30 is fixed on insulation window 22; optionally, snap ring is set; the snap ring sets to outer wall of sleeve and contact with chamber lid to make sleeve grounded through the chamber lid and snap ring. In this embodiment, flanging could be a ring structure around the opening of sleeve, or one or multiple sheet structure; bolts can be set on flanging to fix it to the insulation window 22 to realize enclosed at sleeve opening; the snap ring can be made of metal conducting materials. The sleeve is electrically connected with chamber lid 20 by snap ring so as to realize the sleeve to be grounded. The snap ring could be connected with sleeve 30 by interference fit, and then fixed on chamber lid 20.

The electrode structure used in ICP etcher is described in details as above in this embodiment. In addition, this invention relates to an ICP etcher with aforesaid electrode structure. The aforesaid electrode structure is set on opening of chamber together with the chamber lid. A base is set inside the chamber to hold substrate to be processed. Since electrode structure in this invention is adopted, in substrate processing, the electromagnetic field interference generated by inductive coil connectors is eliminated so as to greatly improve homogeneity of etching and improve quality of etching and yield of products.

Although the content of the present invention has been introduced in detail through the preferred embodiments above, it should be appreciated that the depiction above should not be regarded as a limitation to the present invention. After having read the content above, various modifications and substitutions to the present invention will be obvious to those skilled in the art. Therefore, the protection scope of the present invention should be limited by the appended claims.

1. An electrode structure for ICP etcher, wherein, it includes: inductive coils, inductive coil connectors, connect rods and sleeve; in which,
inductive coils are set on insulation window and insulation window is set on chamber lid of the ICP etcher;
two ends of the connect rods respectively connect inductance coils and inductance coil connectors;
the sleeve is made of conductive material and is grounded; first end of the sleeve is covered by a cap while the second end is opening; the cap has holes, and the connect rods are set pass through the holes and isolated from the cap; the opening of sleeve is set towards inductive coils, and the inductive coils are shielded inside the sleeve.

2. The electrode structure according to claim 1, wherein, the hole diameter on cap is larger than that of the connect rods so the holes and connect rods have gap to realize the isolation between connect rods and cap.

3. The electrode structure according to claim 1, wherein, an insulation pad is set between the holes and connect rods to make connect rods isolate from cap.

4. The electrode structure according to claim 1, wherein, the second end of sleeve sets a flanging, by which the sleeve is fixed ON chamber lid; the flanging contacts with chamber lid so as to make sleeve be grounded through the chamber lid.

5. The electrode structure according to claim 1, wherein, it further contains snap ring, the second end of sleeve sets a flanging, the sleeve is fixed onto insulation window by the flanging; the snap ring sets on outer wall of sleeve and contacts with chamber lid to make sleeve be grounded through the chamber lid and snap ring.

6. The electrode structure according to claim 1, wherein, the conductive material of sleeve is metal Cu, Al or Ag, or their combination, or magnetic shielding metal materials.

7. The electrode structure according to claim 1, wherein, the inductive coils are circular, and the sleeve is cylindrical.

8. The electrode structure according to claim 1, wherein, the part of connect rods covered by the sleeve is arranged vertically.

9. The electrode structure according to claim 1, wherein, multiple connect rods connecting with inductive coils; the first connect rods connect with radio-frequency power supply through the first inductive coil connectors, and the second connect rods connect with grounding end through the second inductive coil connectors.

10. The electrode structure according to claim 1, wherein, it further includes multiple inductive coil connectors, the inductive coil connectors arranged laterally and above the cap of the sleeve.
